(19) United States
(12) Patent Application Publication
(10) Pub. No.: US 2026/0245806 A1
(43) Pub. Date: Aug. 20, 2026

(54) ELECTRET

(71) Applicant: DENSO CORPORATION, Kariya-City (JP)

(72) Inventors: Noriyuki MATSUSHITA, Kariya-City (JP); Takuya IGASHIRA, Kariya-City (JP); Kazuhiko KANO, Kariya-City (JP)

(21) Appl. No.: 19/451,803

(22) Filed: Jan. 16, 2026

Related U.S. Application Data
(63) Continuation of application No. PCT/JP2024/026338, filed on Jul. 23, 2024.

(30) Foreign Application Priority Data
Jul. 24, 2023 (JP) 2023-119797

(51) Int. Cl. H01G 7/02

(52) U.S. Cl. CPC H01G 7/026

(57) ABSTRACT

An electret is formed by subjecting an inorganic dielectric body to a charging process. The inorganic dielectric body is composed of a metal compound containing at least one of Al and Mg. The metal compound is a metal oxide or a metal salt selected from an oxide or salt containing Al, an oxide or salt containing Mg, or a composite oxide containing one or both of Al and Mg. A total molar fraction of Al and Mg among all metal elements contained in the metal compound exceeds 50%.

### CROSS REFERENCE TO RELATED APPLICATIONS

The present application is a continuation application of International Patent Application No. PCT/JP2024/026338 filed on Jul. 23, 2024, which designated the U.S. and claims the benefit of priority from Japanese Patent Application No. 2023-119797 filed on Jul. 24, 2023. The entire disclosures of all of the above applications are incorporated herein by reference.

### TECHNICAL FIELD

The present disclosure relates to an electret.

### BACKGROUND

Electrets are electrically charged materials that provide an electrostatic field to their surroundings. They have been used in applications such as electret condenser microphones and dust-collecting filters. Moreover, in recent years, electrets have been attracting attention for applications to vibration power generation, which is one of the energy harvesting technologies. For example, the practical application of a small vibration energy harvesting device using electrets, as an integrated circuit embedded device used in electrostatic vibration energy harvesters driven by environmental vibrations, is highly anticipated.

### SUMMARY

An electret according to one aspect of the present disclosure is formed by subjecting an inorganic dielectric body to a charging process. The inorganic dielectric body is composed of a metal compound containing at least one of Al and Mg. The metal compound may be a metal oxide or a metal salt selected from an oxide or salt containing Al, an oxide or salt containing Mg, or a composite oxide containing one or both of Al and Mg. The total molar fraction of Al and Mg among all metal elements contained in the metal compound may exceed 50%.

### BRIEF DESCRIPTION OF DRAWINGS

Objects, features and advantages of the present disclosure will become apparent from the following detailed description made with reference to the accompanying drawings. In the drawings:

FIG. 1 is a schematic diagram showing a general configuration of an electret according to a first embodiment;

FIG. 2A is a schematic diagram showing a general configuration of an electret according to an example of a second embodiment;

FIG. 2B is a schematic diagram showing a general configuration of an electret according to another example of the second embodiment;

FIG. 3A is a diagram showing the relationship between a thickness and a surface potential of an inorganic dielectric body in examples after corona charging;

FIG. 3B is a diagram showing the relationship between a thickness and a surface potential of an inorganic dielectric body in the examples after heating;

FIG. 4 is a diagram showing the relationship between a metal compound constituting an inorganic dielectric body, a band gap energy, and a relative permittivity in examples and comparative examples;

FIG. 5 is a diagram showing the relationship between a heat treatment and a surface potential of an electret in examples and comparative examples;

FIG. 6 is a diagram showing the relationship between an elapsed time after electret formation and a surface potential in the examples;

FIG. 7 is a diagram showing the relationship between an elapsed time after electret formation and a surface potential in an example and a comparative example;

FIG. 8 is a diagram showing the relationship between an elapsed time after electret formation and a surface potential in a comparative example; and

FIG. 9 is a diagram showing the relationship between a heat treatment and a surface potential of an electret in examples.

### DETAILED DESCRIPTION

As a constituent material for electrets, for example, organic polymer materials containing fluorine are generally used, and they offer advantages such as high degree of freedom in shaping during thin film formation and excellent controllability of film thickness. On the other hand, since organic polymer materials raise concerns regarding the thermal stability of surface potential and performance degradation over time, investigations into inorganic compound materials with superior thermal stability have been conducted. For example, bulk sintered bodies of hydroxyapatite may be used as electrets. Hydroxyapatite is considered to exhibit a high surface potential after polarization treatment, due to defects of hydroxide ions caused by sintering and dehydration processes.

An electret may also use a composite oxide of a specific composition having a perovskite structure of the ABO₃ type containing two different metal elements, A and B. In the composite oxide used as an electret, at least one of the metal elements A or B is partially substituted with a dopant element having a lower valence, thereby introducing oxygen vacancies. This provides the advantage that the amount of oxygen vacancies can be controlled by adjusting the degree of substitution.

Electrets using hydroxyapatite generate crystal defects during a dehydration process at high temperatures, making it difficult to control the amount of dehydration and the quantity of defects. Furthermore, since a sintering process is required, it is also difficult to form thin films on substrates. Accordingly, the present inventors considered applying composite oxides having a perovskite structure to general integrated circuit manufacturing processes. As a result, it was found that surface potentials of electrets decrease upon exposure to high-temperature treatment or over time. Since device fabrication, such as for vibration power generation elements, involves heat treatment processes, there is a need to realize electrets with higher thermal stability and suppressed decrease in surface potential over time.

An electret according to one aspect of the present disclosure is formed by subjecting an inorganic dielectric body to a charging process, the inorganic dielectric body is composed of a metal compound containing at least one of Al and Mg, and a total molar fraction of Al and Mg among all metal elements contained in the metal compound exceeds 50%.

The electret with the above configuration uses a metal compound as the inorganic dielectric body to be charged, in which the total molar fraction of Al and Mg exceeds 50%. It has been found that even in high-temperature environments of 200° C., the electret can maintain the surface potential generated by polarization and suppress a decrease in the value of the surface potential. Although the reason for this is not entirely clear, for example, it has been observed that similar effects are not obtained when the molar fraction of Al is 50% or less, even in oxides containing Al. Therefore, it is presumed that the increased proportion of Al and Mg among the metal elements contributes to the improvement in thermal stability.

As described above, according to the above aspect, it is possible to provide an electret that can maintain a high surface potential even in high-temperature environments and that exhibits excellent thermal and temporal stability.

### First Embodiment

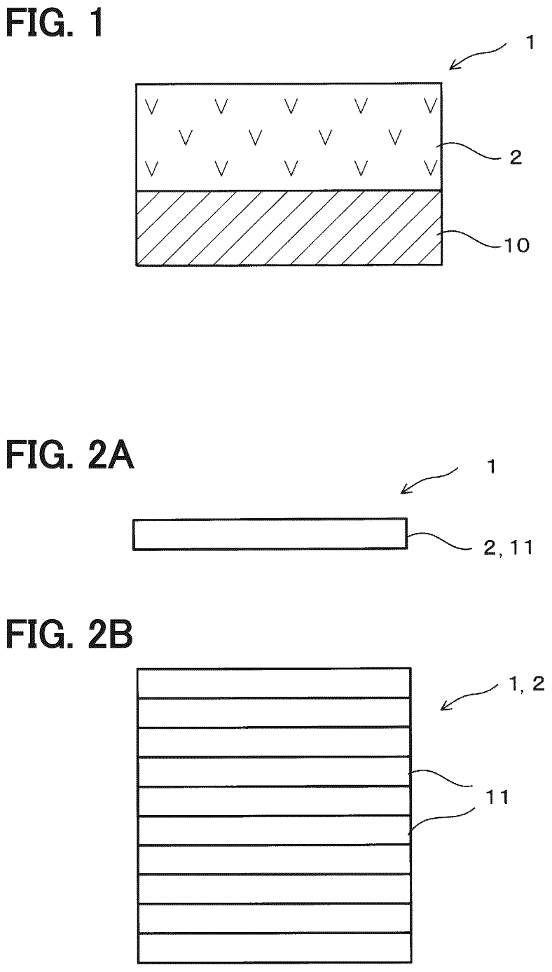

An electret according to a first embodiment will be described with reference to FIG. 1. As shown in FIG. 1, an electret 1 of the present embodiment is formed by charging an inorganic dielectric body 2 composed of a metal compound. The metal compound used as the inorganic dielectric body 2 is a compound containing at least one of Al and Mg as metal elements, and the total molar fraction of Al and Mg relative to all metal elements exceeds 50%. In other words, the metal compound has a composition in which the molar fraction of metal elements other than Al and Mg is 50% or less.

When the total amount of metal elements contained in the metal compound is set to 100% in terms of molar fraction, the total molar fraction of Al and Mg exceeding 50% enables stable maintenance of a high surface potential exhibited by polarization. Specifically, an electret 1 that is less likely to experience performance degradation due to long-term use can be obtained, even under high-temperature environments exceeding 100° C. The form of the inorganic dielectric body 2 is not particularly limited. In the present embodiment, the inorganic dielectric body 2 is formed as a thin film on the substrate 10.

The electret 1 is a charged substance that retains positive or negative charges on its surface and provides an electrostatic field to its surroundings. By subjecting the inorganic dielectric body 2 to a charging process, which will be described later, a surface potential can be generated. The electret 1 can be applied to various devices that convert mechanical energy and electrical energy into each other. For example, the electret 1 can be used as a power generation element integrated into an integrated circuit in electrostatic vibration power generators or the like, which utilize environmental vibrations as a driving source to obtain an output on the order of microwatts to milliwatts.

Specifically, the metal compound may be a metal oxide or a metal salt. The metal oxide or metal salt may be composed such that the main metal element is Al, Mg, or both, and the compound composition is selected so that the total molar fraction of Al and Mg exceeds 50%. The compound may also contain metal elements other than Al and Mg.

From the viewpoint of maintaining a high surface potential with thermal and long-term stability, it is preferable that the total molar fraction of Al and Mg in the metal compound is 60% or more. More preferably, the metal compound may be selected so that the total molar fraction of Al and Mg is 65% or more, and even more preferably, substantially all of the metal elements contained in the metal compound are Al and Mg. Here, “substantially all are Al and Mg” means, for example, that the total molar fraction is 90% or more, preferably 99% or more, and unavoidable impurities derived from starting materials or the like may be included in an amount of about 1%, for example.

Such metal compounds can be selected from oxides or salts containing Al, oxides or salts containing Mg, or composite oxides containing one or both of Al and Mg. There are no particular limitations on the salts containing Al or the salts containing Mg, and examples thereof may include, as appropriate, nitrides, hydroxides, chlorides, carbonates, sulfates, and nitrates.

Specifically, examples of the oxides containing Al include Al₂O₃ (alumina), and examples of the salts containing Al include aluminum salts such as AlN, Al(OH)₃, and Al₂(SO₄)₃. Examples of the oxides containing Mg include MgO (magnesia), and examples of the salts containing Mg include magnesium salts such as MgCO₃, MgSO₄, Mg(NO₃)₂, Mg(OH)₂, and MgCl₂. When these metal oxides or salts are used, the mole fraction of Al or Mg among the total metal elements is 100%.

Examples of the composite oxides containing one or both of Al and Mg include, for instance, MgAl₂O₄ (spinel) or oxides having a basic spinel-type composition represented by the following composition formula 1 (hereinafter referred to as spinel-type oxides):
the composition formula 1: X1Al₂O₄ (wherein X1 is a divalent metal element), or oxides having a basic garnet-type composition represented by the following composition formula 2 (hereinafter referred to as garnet-type oxides):
the composition formula 2: X2₃Al₅O₁₂ (wherein X2 is a trivalent metal element).

In the composition formula 1, the divalent metal element X1 can be at least one element selected from, for example, alkaline earth metal elements such as Mg and Sr, or transition metal elements such as Fe, Zn, and Mn. Specific examples of spinel-type oxides having such a composition include MgAl₂O₄ (spinel), as well as SrAl₂O₄, FeAl₂O₄, ZnAl₂O₄, and MnAl₂O₄. In that case, the total molar fraction of Al and Mg among all metal elements will be 66.7% to 100%.

In the composition formula 2, the trivalent metal element X2 can be at least one element selected from rare earth elements such as Y, or lanthanoids such as La, Sm, and Gd. Specific examples of garnet-type oxides having such a composition include Y₃Al₅O₁₂ and the like. In that case, the molar fraction of Al among all metal elements will be 62.5%.

Here, spinel-type oxides or garnet-type oxides may have a ratio of constituent elements X1 or X2, Al, and O of approximately 1:2:4 or 3:5:12 as a whole, and it is not necessarily required to have a spinel-type crystal structure or garnet-type crystal structure. In such cases, it is not necessary for the entire oxide to have a uniform composition, and it may partially have a composition different from the basic composition.

It is also possible that, in the garnet-type oxide, a part of the trivalent metal element X2 is substituted with a dopant element. Examples of dopant elements include alkaline earth metal elements such as Mg and Sr. When Mg is used as the dopant element, the total molar fraction of Al and Mg increases in accordance with the substitution amount. When introducing the dopant element, for example, it is preferable that the substitution ratio of the dopant element replacing X2 be 20 atm % or less.

The electret 1 can be obtained by subjecting the inorganic dielectric body 2, which is composed of such a metal compound, to a charging process. As a method for the charging process, a method may be employed in which a voltage is applied between a grounded electrode and a counter electrode connected to the inorganic dielectric body 2, using corona discharge or the like. In addition to the method using corona discharge, the charging process may also be performed by thermal electret formation, in which a high voltage is applied at high temperatures, or by other similar methods.

The metal compound may be either a crystalline compound or a non-crystalline compound, and the shape and form of the inorganic dielectric body 2 can be appropriately selected according to the application and required properties. For example, as shown in FIG. 1, the inorganic dielectric body 2 can be formed as an amorphous film on the substrate 10, and it is possible to make the inorganic dielectric body 2 into a thin film of 0.1 mm (100 μm) or less. Preferably, a film of the inorganic dielectric body 2 having a desired thickness in the range of about 0.01 μm to several tens of μm can be easily formed, for example, by using a sputtering method or the like.

When a sputtering method or the like is used as the film formation method, a polycrystalline body of the desired metal compound may be used as a target, and by applying a high voltage in an inert gas atmosphere, an amorphous film having a similar composition can be formed. The film formation method is not limited to sputtering and any suitable method can be employed. Other methods include physical vapor deposition (PVD), chemical vapor deposition (CVD), sol-gel methods, and fusion methods, and the like. The appropriate method may be selected as needed, taking into consideration the desired film quality and thickness.

The substrate 10 is not particularly limited, and for example, a conductive substrate made of (Nb,Sr)TiO₃, Si, or the like can be used. In addition, a conductive substrate using a conductive material such as metal or an insulating substrate using a glass material or the like can also be used. The substrate 10 and the inorganic dielectric body 2 may have any external shape, such as a rectangular plate or a disk, for example.

The form of the inorganic dielectric body 2 is not limited to the amorphous film described above and may also be a crystalline film, such as a polycrystalline film. Alternatively, a plate-shaped single crystal or polycrystal may be used as the inorganic dielectric body 2. Next, an example will be described.

### Second Embodiment

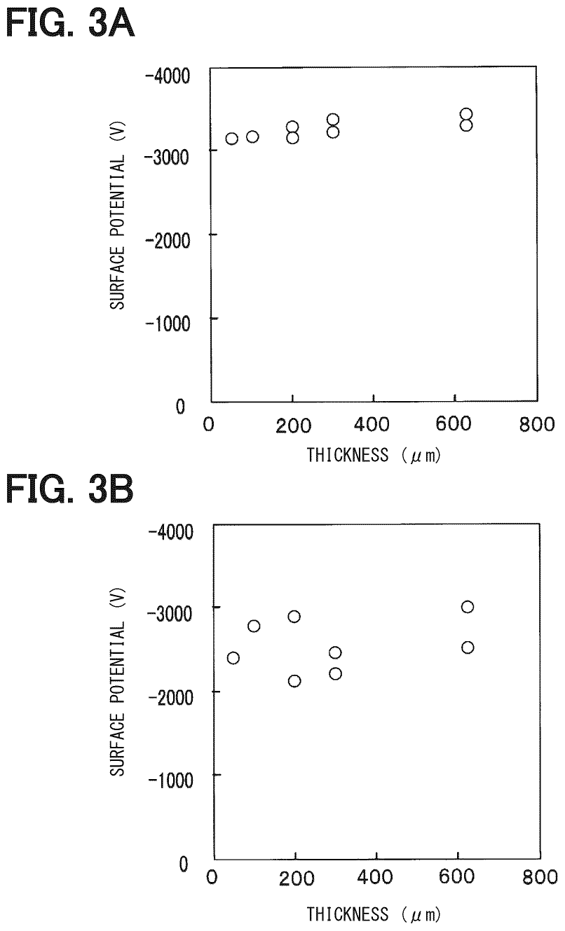

An electret according to a second embodiment will be described with reference to FIGS. 2A and 2B and FIGS. 3A and 3B. Incidentally, among reference numerals used in the second and subsequent embodiments, the same reference numerals as those used in the embodiment already described represent the same components as those in the embodiment already described, unless otherwise indicated.

In the present embodiment, the substrate 10 used in the first embodiment is omitted, and as shown in FIGS. 2A and 2B, a predetermined thin plate-shaped single crystal 11 is used as the inorganic dielectric body 2. The single crystal 11 may be any of the various metal compounds described above, and for example, an alumina single crystal having a sapphire (α-Al₂O₃) structure can be used. The inorganic dielectric body 2 is not limited to the single crystal 11, and a polycrystal may also be used as the inorganic dielectric body 2.

As shown in FIG. 2A, the single crystal 11 with a plate-like shape can be used alone. However, as shown in FIG. 2B, a stacked body in which multiple single crystals 11 with plate-like shapes are stacked may be used to form the inorganic dielectric body 2 with a stacked structure. In that case, a predetermined number of single crystals 11 with plate-like shapes may each be made into electrets and then stacked together to form an integrated body. By adopting a stacked structure for the electret 1, the surface potential of the integrated inorganic dielectric body 2 becomes nearly equal to the sum of the surface potentials of the single crystals 11, enabling a high surface potential corresponding to the number of layers.

As will be described in detail later (see Example 2), it has been found in FIGS. 3A and 3B that the surface potential of the inorganic dielectric body 2 does not significantly change depending on its thickness. Therefore, when using the inorganic dielectric body 2 with a stacked structure, the plate thickness of each single crystal 11 and the number of layers can be appropriately combined to achieve desired properties according to the intended application or other requirements. Preferably, by setting the thickness of each single crystal 11 to 100 μm or less, for example, about several tens of micrometers, it is possible to enhance the electret performance while suppressing an increase in the size of the inorganic dielectric body 2.

For example, when a stacked body is formed by using ten single crystals 11 each having a thickness of 50 μm, the total plate thickness of the inorganic dielectric body 2 becomes 0.5 mm (500 μm), and it is possible to obtain a surface potential up to ten times higher than that obtained using a single crystal 11 of the same total thickness. It has been confirmed that, in such a stacked body, adjacent single crystals 11 are closely adhered and integrated with each other, making it possible to obtain an electret 1 that efficiently exhibits the desired electret performance with a simple structure.

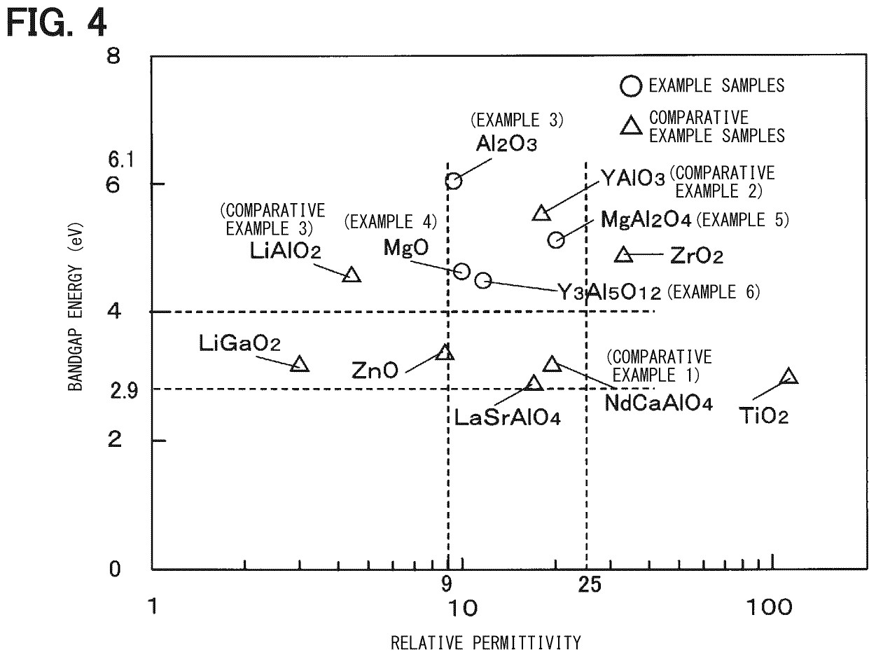

As shown in FIG. 4, in the first and second embodiments, it is preferable that the metal compound used as the inorganic dielectric body 2 has a band gap energy and a relative permittivity within predetermined ranges. Here, metal compounds having a band gap energy of 2.9 eV or higher are exemplified, and by using metal compounds having a relatively large band gap energy, the dielectric breakdown voltage of the inorganic dielectric body 2 can be increased. Therefore, it becomes possible to apply a high voltage during the charging process and thereby induce a desired high surface potential (for example, 1000 V or higher).

FIG. 4 shows various metal oxides, including the metal compounds used for the inorganic dielectric body 2, and the relationship between their band gap energy and relative permittivity. Among the metal oxides, example samples indicated by circles in the figure (MgO, Al₂O₃, MgAl₂O₄, Y₃Al₅O₁₂) all have a band gap energy of 4 eV or higher, and their relative permittivity falls within the range from 9 to 25, inclusive. In addition, it has been confirmed in the evaluation tests of Examples, which will be described in detail later, that the following conditions 1) to 3) are satisfied (see Examples 3 to 6):
1) The absolute value of the surface potential is 1000 V or higher;
2) The decrease in surface potential after heating at 200° C. following electret formation is 10% or less; and
3) The temporal change in surface potential is small.

In addition, FIG. 4 shows, as comparative example samples, the band gap energy and relative permittivity for each of metal oxides in which the total molar fraction of Al and Mg is 50% or less (LiAlO₂, LaSrAlO₄, NdCaAlO₄, YAlO₃), and metal oxides that do not contain Al or Mg (LiGaO₂, ZnO, ZrO₂, TiO₂). All of these comparative example samples have a band gap energy of 2.9 eV or higher, and the relative permittivity falls within the range from 2 to over 100. It should be noted that the relative permittivity is the ratio of the permittivity (ε) of each sample to the permittivity of a vacuum (ε0) as expressed by the following equation:
The relative permittivity=the permittivity of a substance (ε)/the permittivity of a vacuum (ε0).

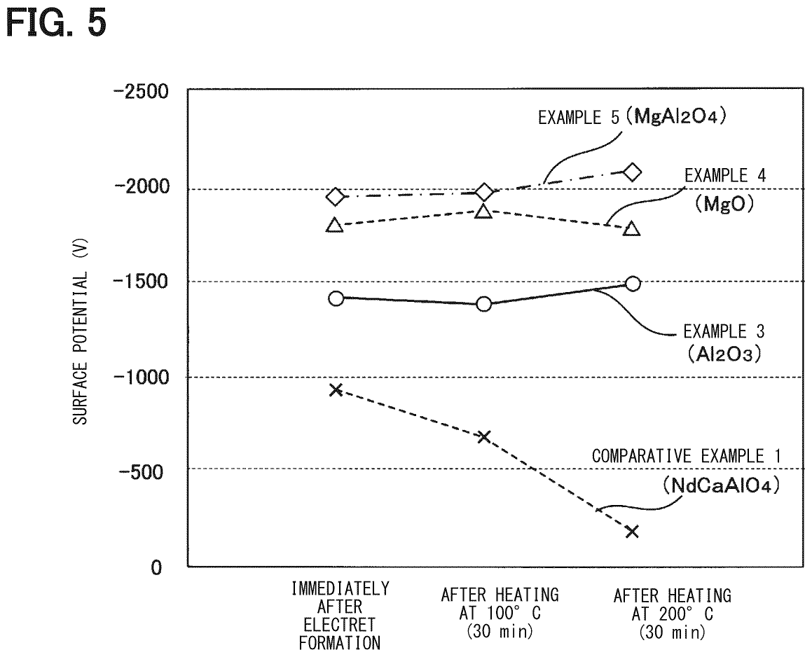

It has been confirmed that the metal oxides of these comparative example samples do not satisfy at least one of the above conditions 1) to 3). In particular, the comparative example samples that do not contain Al or Mg (ZnO, ZrO₂) exhibit band gap energies and relative permittivities relatively close to those of the example samples. However, they hardly express any surface potential. Furthermore, when the relative permittivity falls significantly outside the range equivalent to that of the example samples, sufficient surface potential is not exhibited regardless of the presence or absence of Al or Mg (LiAlO₂, LiGaO₂, TiO₂). Furthermore, in cases where Al or Mg is contained and the relative permittivity is within the range equivalent to that of the example samples, the initial surface potential can be obtained. However, either a decrease in surface potential due to heating is observed, or long-term stability cannot be achieved (see FIGS. 5 to 9). Details of these will be described later.

From these results, it can be seen that in order to achieve the desired surface potential, it is advantageous to use a metal compound containing Al or Mg, in addition to having a band gap energy of 2.9 eV or higher. Specifically, when the total molar fraction of Al and Mg in the metal compound exceeds 50%, it is possible to achieve a thermally and temporally stable surface potential. It is preferable that the band gap energy is 4 eV or higher, and the relative permittivity is in the range of 9 to 25, inclusive.

In this way, by using the inorganic dielectric body 2 having a relative permittivity and band gap energy within the specified ranges, it is possible to obtain the electret 1 that exhibits both the desired high surface potential and stability of the surface potential at high temperatures, as well as long-term stability of the surface potential.

### Example 1

An electret 1 having the configuration shown in FIG. 1 was fabricated by the following method, and its electret performance was evaluated. The electret 1 was prepared by forming a film of a composite oxide having a spinel-type composition containing Mg, Al, and O as an inorganic dielectric body 2 on a substrate 10, and then subjecting it to a charging process. As the substrate 10, a conductive substrate (0.5 mm) composed of SrTiO₃ containing 0.5 mass % Nb was prepared.

### Film Formation

A film containing Mg, Al, and O was formed on the surface of substrate 10 by sputtering, using a pre-prepared polycrystalline spinel (MgAl₂O₄) as a target, under an Ar atmosphere at 360° C. The formed film was an amorphous film containing Mg, Al, and O in an approximate ratio of 1:2:4, with a thickness of 0.3 μm. Subsequently, a heat treatment was performed at 600° C. for 10 hours in air to form a thin film serving as the inorganic dielectric body 2.

### Electret Formation

Next, the substrate 10, on whose surface the thin film serving as the inorganic dielectric body 2 had been formed, was placed on a surface of a grounded heater plate, with a rear surface of the substrate 10 in contact with the heater plate, and subjected to a charging process by corona discharge. The heating temperature provided by the heater plate and the conditions for the charging process by corona discharge were as follows. The corona discharge was carried out by positioning a discharge needle opposite to the surface of the inorganic dielectric body 2 serving as the sample.
Heating temperature: 200° C.
Discharge voltage: −5.5 kV
Discharge time: 3 minutes
Distance between the discharge needle and the sample: 10 mm

### Surface Potential Measurement

The surface potential of the electret 1 (Example 1) obtained as described above was measured. For the measurement, a known surface voltmeter (MODEL 341-B, manufactured by Trek Japan Co., Ltd.) was used to measure the surface potential in a non-contact manner. At this time, the surface potential was measured immediately after the electret formation by the charging process, after heating at 100° C. for 30 minutes, and further after heating at 200° C. for 30 minutes, respectively, to evaluate the effects of thermal environment and elapsed time.

As a result, ions charged by corona discharge collide with the exposed surface of the inorganic dielectric body 2 formed on the substrate 10, causing it to acquire a negative charge and thereby become electret. The obtained electret 1 exhibited a surface potential (absolute value) of approximately 200 V immediately after the charging process, and even after subsequent heating at 100° C. and further heating at 200° C., it retained a surface potential (absolute value) exceeding 100 V. Thus, it was confirmed that using an amorphous film with a spinel-type composition provides high thermal stability.

### Example 2

A metal oxide containing Al was used as the inorganic dielectric body 2, and after subjecting it to a charging process, an electret 1 having the structure shown in FIG. 2A was produced. The metal oxide containing Al was prepared as a single crystal of alumina with a sapphire (α-Al₂O₃) structure, and substrate-shaped samples measuring 10 mm square with various thicknesses were prepared as evaluation samples 1 to 5. Multiple pieces of samples 1 to 5 were prepared, each having the thicknesses indicated below.
Sample 1: 50 μm
Sample 2: 100 μm
Sample 3: 200 μm
Sample 4: 300 μm
Sample 5: 625 μm

For each of Samples 1 to 5, a charging process by corona discharge was performed under the following conditions by placing them on a grounded heater plate in the same manner as in Example 1.
Heating temperature: 200° C.
Discharge voltage: −5.5 kV
Discharge time: 3 minutes
Distance between the discharge needle and the sample: 10 mm

For the electrets 1 of Example 2, the surface potentials were measured in the same manner as in Example 1. The measurements were conducted immediately after electret formation, after heating at 100° C. for 30 minutes, and further after heating at 200° C. for 30 minutes. The respective results are shown in FIGS. 3A and 3B.

In FIG. 3A, the electrets 1 of samples 1 to 5, which used alumina single crystals, all exhibited a high surface potential (absolute value) exceeding 3000 V immediately after electret formation, with little variation among them. As shown in FIG. 3B, after heating at 100° C. and 200° C., an overall decrease in surface potential was observed, and the variation became somewhat larger. However, a high surface potential (absolute value) exceeding 2000 V to over 3000 V was maintained, indicating excellent thermal stability.

Furthermore, since there is hardly any difference in surface potential due to the thickness of samples 1 to 5, it is inferred that the charging by corona discharge is concentrated in surface layers (for example, within 50 μm) of the electrets 1. Therefore, for example, as shown in FIG. 2A, when an alumina single crystal is used alone, it is possible to obtain substantially equivalent characteristics regardless of thickness by forming it into a thin plate having a thickness of about 50 μm or more. In addition, as shown in FIG. 2B, when the electret 1 is configured by stacking alumina single crystals, single crystals of any thickness can be combined so as to achieve the desired characteristics or total stacked thickness. As one example, by forming an electret 1 by stacking ten layers of alumina single crystals of the samples 1 to 5, the total stacked thickness can be in the range of about 0.5 mm to several millimeters, making it possible to achieve a high surface potential (absolute value) of about 20 kV to 30 kV, which would be difficult to realize with a single sintered body of equivalent thickness.

### Examples 3-5

Electrets 1 were produced by using metal oxides of various compositions containing at least one of Al and Mg as the inorganic dielectric body 2, and subjecting them to a charging process. First, as the inorganic dielectric body 2, a sample was prepared using an alumina single crystal with a sapphire (α-Al₂O₃) structure, similar to Example 2, in the form of a substrate with dimensions of 10 mm square and a thickness of 0.5 mm (500 μm), and subjected to a charging process by corona discharge (Example 3). The charging process was carried out under the conditions described below, in the same manner as in Example 1, by placing the sample on a heater plate and heating it.
Heating Temperature: 200° C.
Discharge voltage: −5.5 kV
Discharge time: 3 minutes
Distance between the discharge needle and the sample: 10 mm

In addition, as the inorganic dielectric body 2, a sample using a magnesia single crystal (Example 4) and a sample using a spinel single crystal (Example 5) were each prepared in the form of a substrate similar to that in Example 3, and subjected to the same charging process to produce the electrets 1. For the electrets 1 in Examples 3 to 5, the surface potentials were measured in the same manner as in Example 1. The measurements were conducted immediately after electret formation, after heating at 100° C. for 30 minutes, and further after heating at 200° C. for 30 minutes. The respective results are shown in FIG. 5 as immediately after electret formation, after heating at 100° C. (30 min), and after heating at 200° C. (30 min).

In FIG. 5, the electret 1 using the alumina single crystal of Example 3 exhibits a surface potential (absolute value) close to 1500 V both immediately after electret formation and after heating at 100° C., and shows an even higher value exceeding 1500 V after heating at 200° C. Furthermore, the electret 1 using the magnesia single crystal of Example 4 exhibits a surface potential (absolute value) of approximately 1800 V under all conditions, and the electret 1 using the spinel single crystal of Example 5 exhibits a surface potential (absolute value) of approximately 2000 V, both of which are higher than that observed in Example 3. Additionally, the decrease in surface potential due to heating is minimal, and in some cases, the surface potential is rather increased.

From FIG. 5, it was confirmed that each of the electrets 1 of Examples 3 to 5 has a surface potential (absolute value) of 1000 V or higher, and that the decrease in surface potential (absolute value) after heating at 200° C. is within 10%. Thus, it can be seen that by using a single crystal containing at least one of Al and Mg, the surface potential after electret formation is significantly increased, and the effect of suppressing the decrease in surface potential under high temperature environments is enhanced, resulting in greatly improved thermal stability.

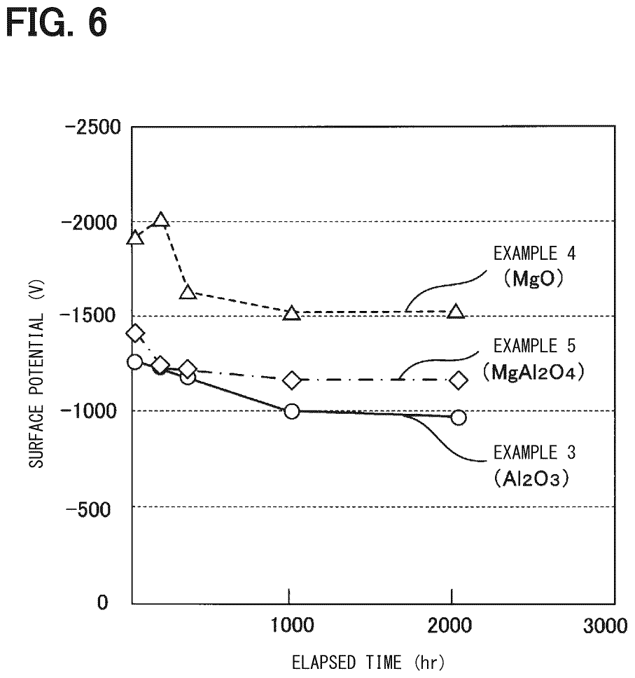

In addition, FIG. 6 shows the results of evaluating changes in surface potential over time for similar samples prepared using the metal oxides of Examples 3 to 5. In FIG. 6, the elapsed time on the horizontal axis (unit: hr) excludes the respective 30-minute heating periods at 100° C. and 200° C. after the above-described electret formation. The surface potential measured at the point when these heating periods have elapsed is defined as the surface potential at elapsed time 0. Subsequently, the relationship between elapsed time and surface potential was investigated over a period of up to 2000 hours.

As shown in FIG. 6, although the electrets 1 using the metal oxides of Examples 3 to 5 each exhibit a tendency for the surface potential (absolute value) to decrease over time, the decrease is not significant, and the surface potential is almost stabilized by 1000 hours. Furthermore, subsequent changes are minimal, and even after 2000 hours, a high surface potential (absolute value) of more than 1000 V to over 1500 V is maintained.

### Comparative Example 1

For comparison, an electret 1 was prepared by using, as the inorganic dielectric body 2, a metal oxide containing 50 mol % or more of a metal element other than Al or Mg, and subjecting it to the same charging process as in Example 1. As the inorganic dielectric body 2 of Comparative Example 1, a single crystal of NdCaAlO₄ containing Nd, Ca, and Al in equal proportions was used, and a substrate-shaped sample similar to that in Example 3 was prepared. At this time, the mole fraction of Al was approximately 33.3% (that is, the total mole fraction of Al and Mg was less than 50%).

For the electret 1 of Comparative Example 1, the surface potential was measured in the same manner as in Example 1, and the results are shown in FIG. 5. As shown in FIG. 5, the surface potential (absolute value) of the electret 1 in Comparative Example 1 immediately after electret formation is less than 1000 V, which is lower than that of the electret 1 in Examples 3 to 5. In addition, a decrease in the surface potential (absolute value) was observed upon heating at 100° C., and after heating at 200° C., the surface potential (absolute value) had significantly dropped to around 200 V.

From the results shown in FIG. 5 and FIG. 6, it can be understood that by using a metal oxide as the inorganic dielectric body 2 in which the total mole fraction of Al and Mg exceeds 50%, the electret performance is improved, resulting in electret 1 exhibiting a high surface potential (absolute value) of 1000 V or higher, as well as excellent thermal and temporal stability.

### Example 6 and Comparative Example 2

As the inorganic dielectric body 2, a single crystal with a garnet-type composition containing Al and Y (Y₃Al₅O₁₂) was used, and a substrate-shaped sample was prepared in the same manner as in Example 3, subjected to a charging process, and an electret 1 was produced (Example 6). For comparison, a single crystal with a perovskite-type composition containing Al and Y (YAlO₃) was similarly used to produce an electret 1 (Comparative Example 2). In Example 6, the proportion of Al among all the metal elements (mole fraction) is 62.5%, while in Comparative Example 2, it is 50%.

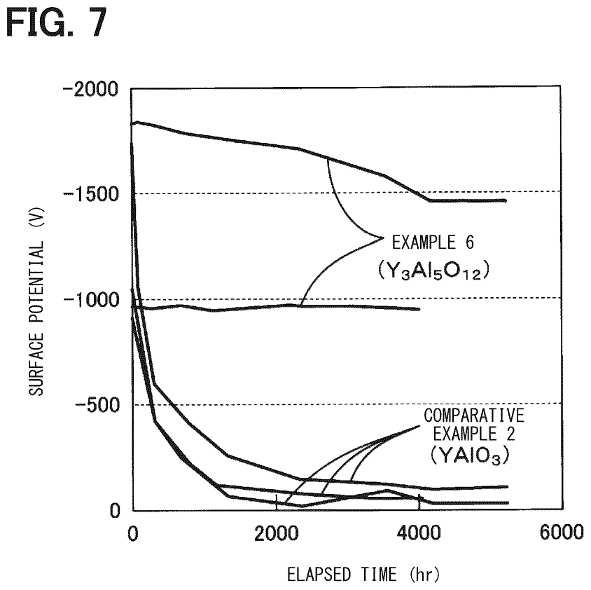

For the electrets 1 in Example 6 and Comparative Example 2, multiple test samples were prepared for each, and the results of the temporal stability tests are shown in FIG. 7. At this time, in the same manner as in Example 1, the sample was subjected to heating at 100° C. for 30 minutes and then at 200° C. The surface potential of the sample after the heat treatment was measured as the surface potential at the start of the test (elapsed time: 0), and changes in surface potential were investigated over an elapsed time exceeding 4000 to 5000 hours. It was also confirmed that the electret 1 of Example 6 has a surface potential (absolute value) of 1000 V or higher, and that the decrease in the surface potential (absolute value) after heating at 200° C. is within 10%.

As shown in FIG. 7, although the surface potential (absolute value) of the electret 1 of Example 6 at the start of the test varied from approximately 1000 V to 1800 V, no significant decrease in surface potential over time was observed, or any decrease was relatively small. Therefore, even after an elapsed time of 4000 hours, a high surface potential of approximately 1000 V to 1500 V is maintained. In contrast, the electret 1 of Comparative Example 2 exhibited a surface potential (absolute value) at the start of the test that was in approximately the same range as Example 6. However, the surface potential rapidly decreased after the start of the test, converging to around 200 V or less after approximately 2000 hours of elapsed time.

From these results, it can be seen that even in cases such as Example 6 and Comparative Example 2, in which the constituent elements of the metal oxide serving as the inorganic dielectric body 2 are the same and there is no significant difference in the initial surface potential (absolute value) after electret formation, Comparative Example 2, in which the molar fraction of Al among the metal elements is 50% or less, exhibits greatly reduced stability over time.

### Comparative Example 3

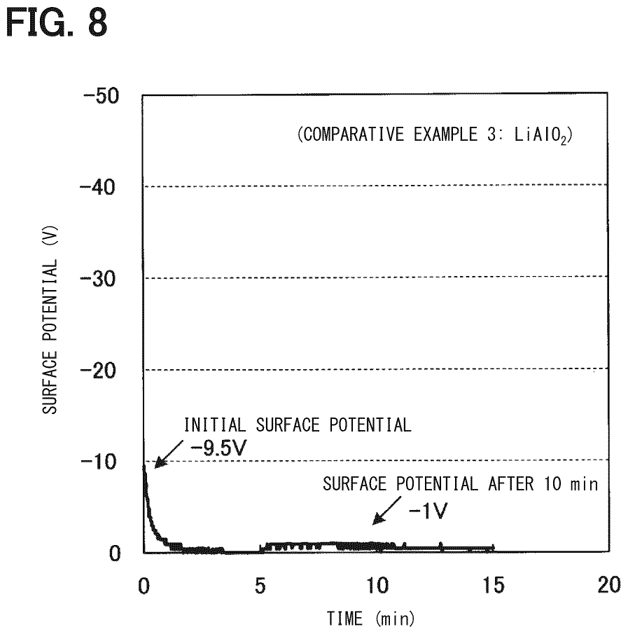

For comparison, a single crystal of LiAlO₂ containing Al and Li in an equimolar ratio was used as the inorganic dielectric body 2, and a substrate-shaped sample was prepared in the same manner as in Example 3. This sample was subjected to a charging process to produce an electret 1. For the electret 1 of Comparative Example 3, the surface potential was measured from immediately after electret formation up to 15 minutes later, as shown in FIG. 8.

Furthermore, in FIG. 4, the relationship between the band gap energy and the relative permittivity is shown for the metal oxides constituting the inorganic dielectric body 2 in Examples 3 to 6 and Comparative Examples 1 to 3, as well as for oxides having similar compositions to these. As described above, the metal oxides of Examples 3 to 6 all have a band gap energy of 4 eV or higher and a relative permittivity in the range from 9 to 25, whereas the metal oxide of Comparative Example 3 has a relative permittivity outside this range.

As shown in FIG. 8, the electret 1 of Comparative Example 3 exhibited a low initial surface potential (absolute value) of 9.5 V immediately after electret formation, which decreased to 1 V after 10 minutes. As shown in FIG. 4, the electret 1 of Comparative Example 3 has a higher band gap energy than the LiGaO₂ single crystal having a similar composition, and is equivalent to those of Examples 3 to 6. In general, elements with smaller atomic numbers tend to increase the band gap energy. Therefore, it is considered that the inclusion of Al (or Mg) results in a higher band gap energy than metal oxides having similar compositions. However, in addition to the fact that the molar fraction of Al is 50% or less, the relative permittivity is lower than the range in Examples 3 to 6. Therefore, it is presumed that the surface potential is not sufficiently exhibited and the temporal stability is also reduced.

### Example 7

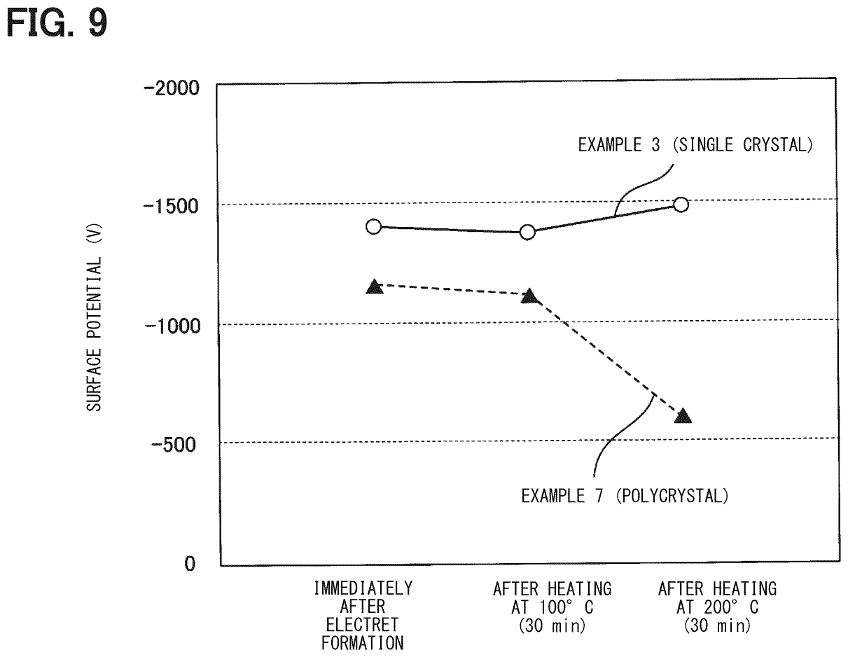

As the inorganic dielectric body 2, a polycrystalline alumina (α-Al₂O₃ sintered body) was used, and a substrate-type sample similar to that of Example 3 was prepared. This sample was subjected to a charging process to produce an electret 1. For the electret 1 of Example 7, the surface potential was measured in the same manner as in Example 1, and the results are shown in FIG. 9 together with the results of Example 3.

As shown in FIG. 9, the electret 1 of Example 7 exhibits a high initial surface potential (absolute value) immediately after electret formation, at approximately 1200 V. The surface potential (absolute value) shows no significant change even after heating at 100° C. However, after heating at 200° C., the surface potential decreases to approximately 600 V. From these results, it can be seen that when a polycrystalline alumina is used, although its stability at high temperatures of 200° C. or higher is inferior to that of the single crystal alumina of Example 3, it is still capable of maintaining a relatively high surface potential (absolute value).

Thus, by using the inorganic dielectric body 2 comprising a metal compound containing at least one of Al and Mg, the thermal and temporal stability of the electret 1 can be greatly improved. Furthermore, in the production of the electret 1, the form such as single crystal, polycrystal, or amorphous film can be appropriately selected. For example, by selecting among these forms according to the usage environment, required shape, or performance, it is possible to obtain a highly practical electret 1.

Although the present disclosure is described based on the above-described embodiments, the present disclosure is not limited to the above-described embodiments and the structures. The present disclosure encompasses various modifications and variations within the scope of equivalents. In addition, various combinations and forms, as well as other combinations or forms including more, less, or only a single element, also fall within the scope and spirit of the present disclosure.

The present disclosure is not limited to each of the above-described embodiments, and can be applied to various embodiments without departing from the gist thereof.

What is claimed is:

1. An electret formed by subjecting an inorganic dielectric body to a charging process, wherein
the inorganic dielectric body is composed of a metal compound containing at least one of Al and Mg,
the metal compound is a metal oxide or a metal salt selected from an oxide or salt containing Al, an oxide or salt containing Mg, or a composite oxide containing one or both of Al and Mg, and
a total molar fraction of Al and Mg among all metal elements contained in the metal compound exceeds 50%.

2. The electret according to claim 1, wherein
the composite oxide is an oxide having a basic composition represented by the following composition formula 1 or an oxide having a basic composition represented by the following composition formula 2:
the composition formula 1: X1Al₂O₄, where X1 is a divalent metal element; and
the composition formula 2: X2₃Al₅O₁₂, wherein X2 is a trivalent metal element.

3. The electret according to claim 2, wherein
X1 in the composition formula 1 is at least one element selected from alkaline earth metal elements or transition metal elements.

4. The electret according to claim 2, wherein
X2 in the composition formula 2 is at least one element selected from rare earth elements.

5. The electret according to claim 1, wherein
the total molar fraction of Al and Mg among all the metal elements contained i the metal compound exceeds 60%.

6. The electret according to claim 1, wherein
the metal compound has a relative permittivity in a range from 9 to 25, inclusive.

7. The electret according to claim 1, wherein
the metal compound has a band gap energy of 4 eV or higher.

8. The electret according to claim 1, wherein
the inorganic dielectric body is a single crystal, a stacked body of single crystals, a polycrystal, or an amorphous film.

9. The electret according to claim 8, wherein
the oxide or salt containing Al or the oxide or salt containing Mg is a single crystal, a stacked body of single crystals, or a polycrystal.
